(19) United States
(12) Patent Application Publication
(10) Pub. No.: US 2008/0280426 A1
(43) Pub. Date: Nov. 13, 2008

(54) Gallium nitride-on-silicon interface

(75) Inventors: Tingkai Li, Vancouver, WA (US); Douglas J. Tweet, Camas, WA (US); Jer-Shen Maa, Vancouver, WA (US); Sheng Teng Hsu, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/801,210

(22) Filed: May 9, 2007

(51) Int. Cl. H01L 29/739; H01L 21/20

(52) U.S. Cl. 438/492; 257/201; 257/E29.194; 257/E21.09

(57) ABSTRACT

A method is provided for forming a matching thermal expansion interface between silicon (Si) and gallium nitride (GaN) films. The method provides a (111) Si substrate and forms a first aluminum (Al)-containing film in compression overlying the Si substrate. Nano-column holes are formed in the first Al-containing film, which exposes regions of the underlying Si substrate. A layer of GaN layer is selectively grown from the exposed regions, covering the first Al-containing film. The GaN is grown using a lateral nanoheteroepitaxy overgrowth (LNEO) process. The above-mentioned processes are reiterated, forming a second Al-containing film in compression, forming nano-column holes in the second Al-containing film, and selectively growing a second GaN layer. Film materials such as Al₂O₃, Si1-xGex, InP, GaP, GaAs, AlN, AlGaN, or GaN, may be initially grown at a low temperature. By increasing the growth temperatures, a compressed layer of epitaxial GaN can be formed on a Si substrate.

### BACKGROUND OF THE INVENTION

1. Field of the Invention

This invention generally relates to integrated circuit (IC) fabrication and, more particularly to a gallium nitride-on-silicon interface and associated fabrication process.

2. Description of the Related Art

Gallium nitride (GaN) is a Group III/Group V compound semiconductor material with wide bandgap (3.4 eV), which has optoelectronic, as well as other applications. Like other Group III nitrides, GaN has a low sensitivity to ionizing radiation, and so, is useful in solar cells. GaN is also useful in the fabrication of blue light-emitting diodes (LEDs) and lasers. Unlike previous indirect bandgap devices (e.g., silicon carbide), GaN LEDs are bright enough for daylight applications. GaN devices also have application in high power and high frequency devices, such as power amplifiers.

GaN LEDs are conventionally fabricated using a metalorganic chemical vapor deposition (MOCVD) for deposition on a sapphire substrate. Zinc oxide and silicon carbide (SiC) substrate are also used due to their relatively small lattice constant mismatch. However, these substrates are expensive to make, and their small size also drives fabrication costs. For example, the state-of-the-art sapphire wafer size is relatively small when compared to silicon wafers. The most commonly used substrate for GaN-based devices is sapphire. The low thermal and electrical conductivity constraints associated with sapphire make device fabrication more difficult. For example, all contacts must be made from the top side. This contact configuration complicates contact and package schemes, resulting in a spreading-resistance penalty and increased operating voltages. The poor thermal conductivity of sapphire [0.349 (W/cm-° C.)], as compared with that of Si [1.49 (W/cm-° C.)] or SiC, also prevents efficient dissipation of heat generated by high-current devices, such as laser diodes and high-power transistors, consequently inhibiting device performance.

To minimize costs, it would be desirable to integrate GaN device fabrication into more conventional Si-based IC processes, which has the added cost benefit of using large-sized (Si) wafers. Si substrates are of particular interest because they are less expansive and they permit the integration of GaN-based photonics with well-established Si-based electronics. The cost of a GaN heterojunction field-effect transistor (HFET) for high frequency and high power application could be reduced significantly by replacing the expensive SiC substrates that are conventionally used.

FIG. 1 is a graph depicting the lattice constants of GaN, Si, SiC, AlN and sapphire (prior art). There are two fundamental problems associated with GaN-on-Si device technology. First, there is a lattice mismatch between Si and GaN. The difference in lattice constants between GaN and Si, as shown in the figure, results in a high density of defects from the generation of threading dislocations. This problem is addressed by using a buffer layer of AlN, InGaN, AlGaN, or the like, prior to the growth of GaN. The buffer layer provides a transition region between the GaN and Si.

FIG. 2 is a graph depicting the thermal expansion coefficients (TECs) of GaN, Si, SiC, AlN, and sapphire (prior art). An additional and more serious problem exists with the use of Si, as there is also a thermal mismatch between Si and GaN. GaN-on-sapphire experiences a compressive stress upon cooling. Therefore, film cracking is not as serious of an issue as GaN-on-Si, which is under tensile stress upon cooling, causing the film to crack when the film is cooled down from the high deposition temperature. The thermal expansion coefficient mismatch between GaN and Si is about 54%.

The film cracking problem has been analyzed in depth by various groups, and several methods have been tested and achieve different degrees of success. The methods used to grow crack-free layers can be divided into two groups. The first method uses a modified buffer layer scheme. The second method uses an in-situ silicon nitride masking step. The modified buffer layer schemes include the use of a graded AlGaN buffer layer, AlN interlayers, and AlN/GaN or AlGaN/GaN-based superlattices.

Although the lattice buffer layer may absorb part of the thermal mismatch, the necessity of using temperatures higher than 1000° C. during epi growth and other device fabrication processes may cause wafer deformation. The wafer deformation can be reduced with a very slow rate of heating and cooling during wafer processing, but this adds additional cost to the process, and doesn't completely solve the thermal stress and wafer deformation issues.

It is generally understood that a buffer layer may reduce the magnitude of the tensile growth stress and, therefore, the total accumulated stress. However, from FIG. 2 it can be seen that there is still a significant difference in the TEC of these materials, as compared with GaN. Therefore, thermal stress remains a major contributor to the final film stress.

It would be advantageous if the thermal mismatch problem associated with GaN-on-Si device technology could be practically eliminated by pre-compressing a thermal interface interposed between the GaN and Si layers.

### SUMMARY OF THE INVENTION

The “a” lattice constants of GaN, Si, and sapphire are about 0.319 nanometers (nm), 0.543 nm, and 0.476 nm, respectively. For GaN on Si(111), the relevant comparison is aGaN to a_{Si}/(2^{1/2}) giving a mismatch of about −20.4% at room temperature. For GaN on (0001) oriented sapphire, the relevant comparison is (3/2)^{1/2}×a_{GaN} to aₛₐₚₚₕᵢᵣₑ/2, leading to a mismatch of about +14% at room temperature. Thus, the lattice mismatch between GaN and sapphire is less severe than that between GaN and silicon.

The thermal expansion coefficients for GaN, Si, and sapphire are 4.3e-6 at 300K for a, 3.9e-6 at 300K for c, 2.57e-6 at 300K, and ˜4.0e-6 at 300K for both a and c, respectively, but rises very rapidly with temperature. The thermal expansion mismatch between GaN and Si is more severe than that between GaN and sapphire, as the former system results in GaN films under tensile strain (leading to cracking), and the latter system produces GaN under compressive stress, which causes fewer problems. Therefore, a new structure to release the thermal expansion related stress would be useful for growing GaN on silicon substrates.

The GaN growth temperature is normally 1050° C. or higher. Therefore, when the wafer is cooled down from the growth chamber, the GaN shrinks faster than the silicon substrate, but is partly restrained by the silicon. As a result, a tensile stress is applied to the GaN film that may cause the GaN film to crack. However, if a pre-compressed layer is formed on Si substrates at GaN growth temperatures, the pre-compressed layer reduces the tensile stress as the GaN film is cooled down from growth temperature, and a crack-free GaN film on Si can be made. Film materials such as Al₂O₃, Si1-xGex, InP, GaP, GaAs, AlN, AlGaN, or GaN, may be initially grown at a low temperature. Then, by increasing the growth temperatures, a compressed layer of epitaxial GaN can be formed on a Si substrate.

Accordingly, a method is provided for forming a matching thermal expansion interface between silicon (Si) and gallium nitride (GaN) films. The method provides a (111) Si substrate and forms a first aluminum (Al)-containing film in compression overlying the Si substrate. Using an anodized aluminum oxide (AAO) technology, nano-column holes are formed in the first Al-containing film, which exposes regions of the underlying Si substrate. A layer of GaN layer is selectively grown from the exposed regions, covering the first Al-containing film. The GaN is grown using a lateral nanoheteroepitaxy overgrowth (LNEO) process. The above-mentioned processes are reiterated, forming a second Al-containing film in compression, forming nano-column holes in the second Al-containing film, and selectively growing a second GaN layer using the LNEO process. In some aspects, a chemical mechanical polish (CMP) is applied to the GaN top surface, and a third layer of GaN is grown.

The first and second Al-containing films may be Al or AlN. Alternately, the first and second Al-containing films may be an AlN/graded AlGaN (Al₁₋ₓGaₓN (0<x<1)) stack. In another aspect, the first and second Al-containing films may be an AlN/AlGaN/GaN stack.

Additional details of the above-mentioned method and a GaN-on-Si thermal expansion interface are provided below.

### BRIEF DESCRIPTION OF THE DRAWINGS

FIG. 1 is a graph depicting the lattice constants of GaN, Si, SiC, AlN and sapphire (prior art).

FIG. 2 is a graph depicting the thermal expansion coefficients (TECs) of GaN, Si, SiC, AlN, and sapphire (prior art).

FIG. 3 is a partial cross-sectional view of a silicon (Si)-to-gallium nitride (GaN) thermal expansion interface.

FIG. 4 is a partially cross-sectional view of a variation of the Si-to-GaN thermal expansion interface of FIG. 3.

Table 1 and FIG. 5 depict the lattice and thermal expansion coefficient data, respectively, of GaN on Si related materials.

FIG. 6 through 9 depicts fabrication steps in the completion of the interface of FIG. 3.

FIG. 10 is a flowchart illustrating a method for forming a matching thermal expansion interface between Si and GaN films.

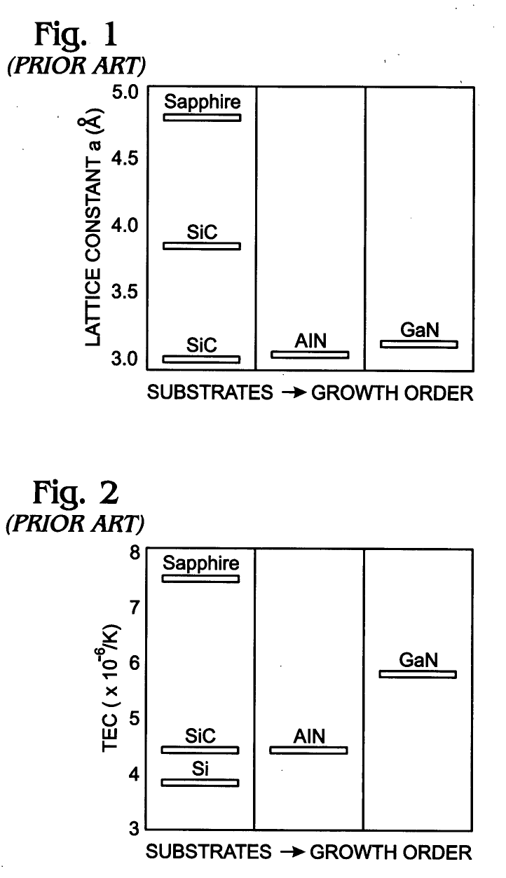

### DETAILED DESCRIPTION

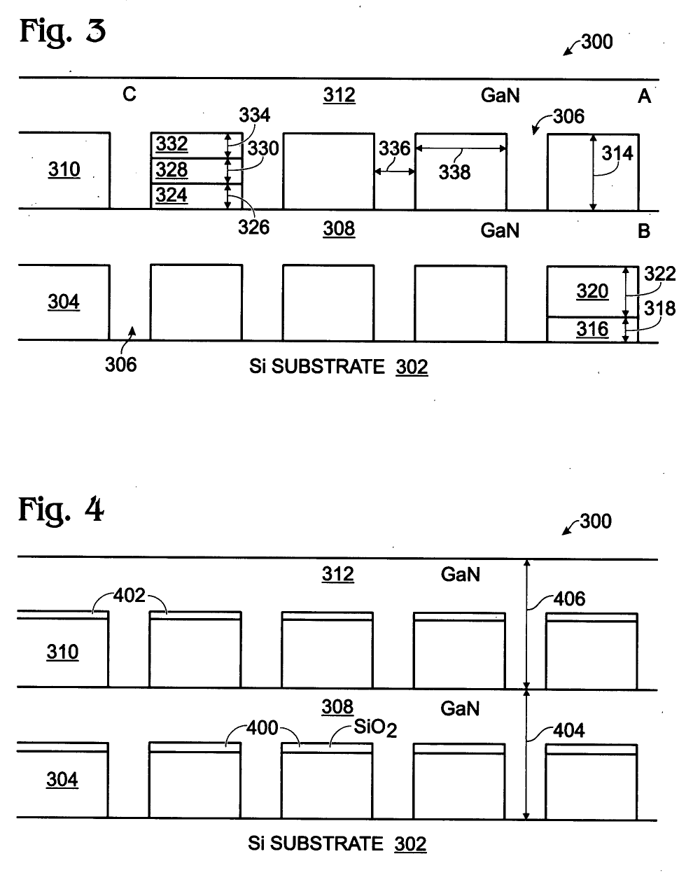

FIG. 3 is a partial cross-sectional view of a silicon (Si)-to-gallium nitride (GaN) thermal expansion interface. The interface 300 comprises a Si substrate 302 with a crystallographic orientation of (111). A first aluminum (Al)-containing film 304 in compression overlies the Si substrate 302, with nano-column holes 306 in the Al-containing film 304 exposing regions of the underlying Si substrate 302. A first layer of GaN 308 is formed in the nano-column holes 306 and overlying the first Al-containing film 304. A second Al-containing film 310 in compression overlies the first GaN layer 308, with nano-column holes 306 in the second Al-containing film 310, exposing regions of the underlying first GaN layer 308. A second GaN layer 312 is formed in the nano-column holes 306 and overlying the second Al-containing film 310.

In one aspect (detail A), the first and second Al-containing films 304 and 310 are an AlN film having a thickness 314 in a range of about 5 to 500 nanometers (nm). Alternately, the first and second Al-containing films 304 and 310 are an Al film having a thickness 314 in the range of 0.5 to 1.5 micrometers. In a second aspect (detail B), the first and second Al-containing films 304 and 310 are an AlN/graded AlGaN (Al₁₋ₓGaₓN (0<x<1)) stack, where the AlN film 316 has a thickness 318 in a range of about 5 to 500 nm and the AlGaN film 320 has a thickness 322 in a range of about 5 to 500 nm. In a third aspect (detail C), the first and second Al-containing films 304 and 310 are an AlN/AlGaN/GaN stack, where the AlN film 324 has a thickness 326 in a range of about 5 to 500 nm, the AlGaN 328 is graded and has a thickness 330 in a range of about 5 to 500 nm, and the GaN 332 has a thickness 334 in a range of about 5 to 500 nm.

In another aspect, the nano-column holes 308 have a diameter 336 in arrange of about 10 to 100 nm, and are separated from adjacent nano-column holes by a distance 338 in a range of about 50 to 200 nm.

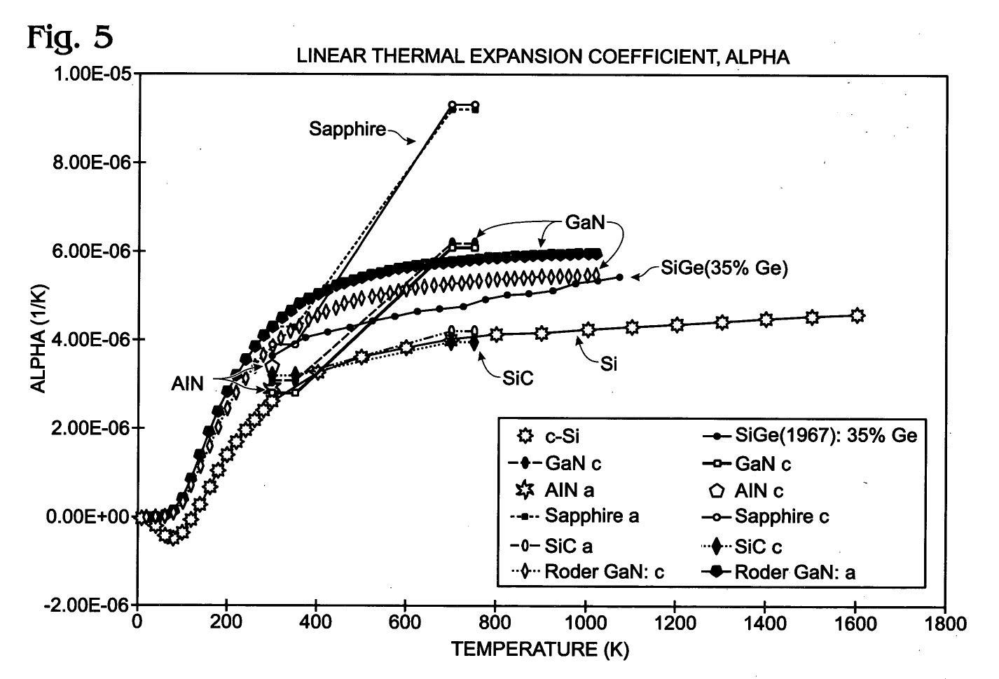

FIG. 4 is a partially cross-sectional view of a variation of the Si-to-GaN thermal expansion interface of FIG. 3. A first layer of Si dioxide 400 is interposed between the first Al-containing film 304 and the first GaN layer 308. Optionally, a second layer of Si dioxide 402 is interposed between the second Al-containing film 310 and the second GaN layer 312.

As applied to both FIG. 3 and FIG. 4 (but only shown in FIG. 4), the first GaN layer 308 has a thickness 404 in a range of 0.3 to 1 micrometers, and the second GaN layer 312 has a thickness 406 in a range of 1 to 4 micrometers.

### Functional Description

A pre-compressed layer is formed on Si substrates at GaN growth temperatures. The pre-compressed layer reduces the tensile stress as the GaN film is cooled down from growth temperature, and a crack-free GaN film on Si can be made. Materials such as Al₂O₃, Si₁₋ₓGeₓ, InP, GaP, GaAs, AlN, AlGaN, and GaN may be initially grown at low temperature, with a subsequent increase to higher temperatures to form a compressed layer. The compressed layer acts as an interface between an epi GaN film and a Si substrate.

When a coating is cooled after deposition, and its thermal expansion coefficient, a_{c}, is larger than that of the substrate, aₛ, (as in the case of GaN on Si), the coating is under tensile strain. As a result, the uncracked film-substrate composite bends, having a radius of curvature, ρ, as

1/ρ=(aₛ−a_{c})(T_{f}−T_{g})/[h/2+2(E_{c}*I_{c}+Eₛ*Iₛ)/h(1/E_{c}*t_{c}+1/Eₛ*tₛ)] (1)

where T_{f} is the final temperature after cooling; T_{g} is the growth temperature; t_{c} and tₛ are the individual coating and substrate thicknesses; h is the total thickness (h=t_{c}+tₛ); I is the moment of inertia, I=t³/12; and E* is the effective modulus of elasticity. These conditions apply for wide layers and plane strain conditions E*=E/(12−v²), where E is the Young's modulus of elasticity and v is the Poisson's ratio.

From formula (1), the quantity [h/2+2(E_{c}*I_{c}+Eₛ*Iₛ)/h(1/E_{c}*t_{c}+1/Eₛ*tₛ)] is called A. A decreases with an increase in the thickness of the coating materials. But if tc<<ts, the coating thickness effect for A can be ignored. The formula (1) changes to

1/ρ=(aₛ−a_{c})(T_{f}−T_{g})/A (2)

Since the coating is thin (t_{c}<0.1 ts), the predicted inplane normal stress in the uncracked coating is uniform and is given by

σₚ=1/ρ[2/ht_{c}(E_{c}*I_{c}+Eₛ*Iₛ)+E_{c}*t_{c}/2] (3)

The quantity [2/ht_{c}(E_{c}*I_{c}+Eₛ*Iₛ)+E_{c}*t_{c}/2] is called B. B increases with an increase in the thickness of coating materials. The formula (3) changes to

σₚ=B(aₛ−a_{c})(T_{f}−T_{g})/A (4)

Let B/A=R, which increases with an increase in the thickness of the coating materials. The formula (4) can be written as

σₚ=R(aₛ−a_{c})(T_{f}−T_{g}) (5)

From formula (5), when the thermal expansion coefficient of the coating material is larger than that of the substrate and is deposited at higher temperatures, the coating materials are under tensile stress (σₚ>0) after cooling down. In contrast, when the thermal expansion coefficient of the coating material is larger than that of the substrate and deposited at lower temperatures, the coating materials is under compressive stress (σₚ<0) when heated to higher temperatures.

Therefore, if materials are grown with a higher thermal expansion coefficient on Si substrates at lower temperatures, the coated materials will be under compression when the wafer is heated to higher temperature, such as the temperatures required for GaN growth. During the wafer cooling down process, the compressed layer reduces the tensile stress of the overlying GaN films, and a crack-free GaN film on a Si substrate is formed.

Table 1 and FIG. 5 depict the lattice and thermal expansion coefficient data, respectively, of GaN on Si related materials. From this data, it can be seen that Al₂O₃, Si₁₋ₓGex, InP, GaP, GaAs, AlN, AlGaN, and GaN, etc., may be used to make a pre-compressed layer on Si substrates. Ge, InP, GaP, and GaAs, etc., can be grown at lower temperatures. AlN has been successfully grown on Si at room temperature. Al₂O₃ can be coated on Si substrates by AAO processes, GaN can also be grown below 700° C., and the temperature increased for epitaxial (epi) GaN growth. Therefore, there are several materials that can be initially grown on Si at low temperatures, with an increase to higher temperatures, to form a compressed layer for epi GaN deposition.

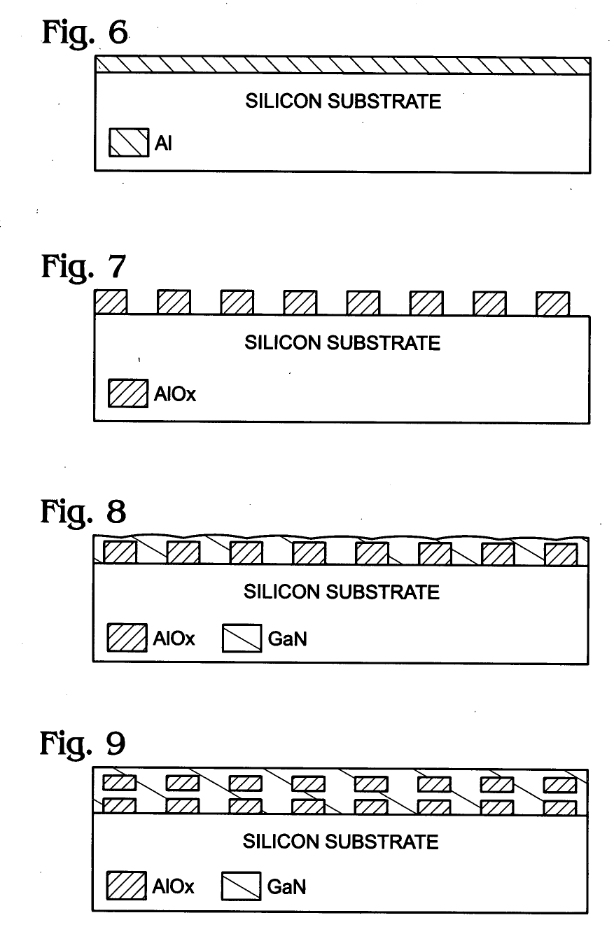

FIG. 6 through 9 depicts fabrication steps in the completion of the interface of FIG. 3. The starting wafer is a <111> oriented silicon substrate. In one aspect, the silicon substrate is cleaned and a 0.5 to 1.5 micrometer (μm) layer of Al is deposited, see FIG. 6. Optionally, the silicon substrate may be cleaned using in-situ hydrogen treatments of the Si substrate, and one of the following films may be deposited: high quality AlN (5-500 nm), or AlN(5-500 nm)/grading AlGaN, or AlN/graded AlGaN (5-500 nm)/GaN (5-500 nm).

Alumina nano-column hole with sizes from 10 nm to 100 nm, and with an average distance between two holes of 50 nm to 200 nm, can be obtained by using an anodized aluminum oxide (AAO) technology, as shown in FIG. 7. Optionally but not shown, SiO₂ can be coated on the AAO for GaN selective deposition.

TABLE 1
Crystal structure, lattice parameters, and thermal
expansion coefficient of selected semiconductor materials

| | | Lattice | Thermal | | | |
|---|---|---|---|---|---|---|
| | Crystal | parameter | Expansion Coeff. | Dielectric | Refractive | Bandgap |
| Materials | Structure | (Å) | (×10⁻⁶/° C.)@25° C. | constant (ε) | Index (n) | (eV)@25° C. |
| GaN | W | a = 3.190 (1) | a: 4.3 (7) | 9.5 | | 3.34 (1) |
| | | c = 5.189 (1) | c: 3.9 (7) | | | |
| GaN | Z | a = 4.52 | | | | 3.2–3.3 |
| AlN | W | a = 3.111 (1) | 2.0 (5.3) | 8.5–9 | | 6.02 (1) |
| | | c = 4.978 (1) | 3.0 (4.2) | | | |
| AlN | Z | a = 4.38 | | | | 5.11 |
| Al₂O₃ | R | a = 4.758 | 4.0 (9) | 4.5–8.4 (1) | 1.76 (4) | >8 (4) |
| | | c = 12.991 | 7.5, 8.3 (4) | 8.6–10.6 (4) | | |
| Si | D | a = 5.431 | 2.57 (8) | 11.8 (1) | 3.49 (1) | 1.107 (1) |
| | | | 4.68 (1), 3.59 (6), | | | |
| GaAs | Z | a = 5.653 (1) | 5.4 (1) | 13.2 (1) | | 1.4 |
| 6H—SiC | W | a = 3.076 (1) | 3.3 (4.2) | 10 | 2.654 (1) | 2.9 |
| | | c = 5.048 (1) | (4.7) | | | |
| 3c-SiC | Z | a = 4.348 (1) | 2.7 (2.9) | 9.7 | 2.697 (1) | 2.3 (1) |
| InP | Z | a = 5.869 (1) | 4.6 (1) | 12.4 (1) | 3.1 (1) | 1.27 (1) |
| InN | W | a = 3.533 (1) | 4 | | | 2.0 (1) |
| | | c = 5.693 (1) | | | | 1.89 |
| InN | Z | a = 4.98 | | | | 2.2 |
| GaP | Z | a = 5.451 (1) | 5.3 (1) | 11.1 (1) | 3.2 (1) | 2.24 (1) |
| MgO | C | a = 4.216 (1) | 10.5, 13.5 (4) | 9.65 (4) | 1.74 (4) | >7.8 (4) |
| ZnO | W | a = 3.25 (1) | 2.9 | | | 3.2 (1) |
| | | c = 5.207 (1) | 4.75 | | | |

The lateral nanoheteroepitaxy overgrowth (LENO) of GaN on Si is performed at a higher temperature of about 700-1200° C., as shown in FIG. 8. The steps associated with FIGS. 7 and 8 are repeated. If the surface of the LNEO GaN is not sufficiently flat for device fabrication, an optional CMP may be performed. After CMP, an additional GaN may be grown to form a very smooth GaN film for device fabrication, as shown in FIG. 9.

As noted above, anodized aluminum oxide (AAO) can be used as a nanosized porous alumina template hardmask to form nanosized patterns in Si (111), AlN, graded AlₓGa₁₋ₓN (1≧x≧0), GaN, and other materials, as part of the process of forming a high quality thick GaN overgrowth. For example, high quality aluminum films can be deposited on a silicon substrate using E-beam evaporation, with a film thickness of 0.5 to 1.5 μm. Both oxalic and sulfuric acid may be used in the anodization process. In a first step, the aluminum coated wafers are immersed in acid solution at 0° C. for 5 to 10 minutes for an anodization treatment. Then, the alumina formed in the first anodic step is removed by immersion in a mixture of H₃PO₄ (4-16 wt %) and H₂Cr₂O₄ (2-10 wt %) for 10 to 20 minutes. After cleaning the wafer surface, the aluminum film is exposed to a second anodic treatment, the same as the first step described above. Finally, the porous alumina template is further treated in 2-8 wt % H₃PO₄ aqueous solution for 15 to 90 minutes to increase the nano-column hole sizes.

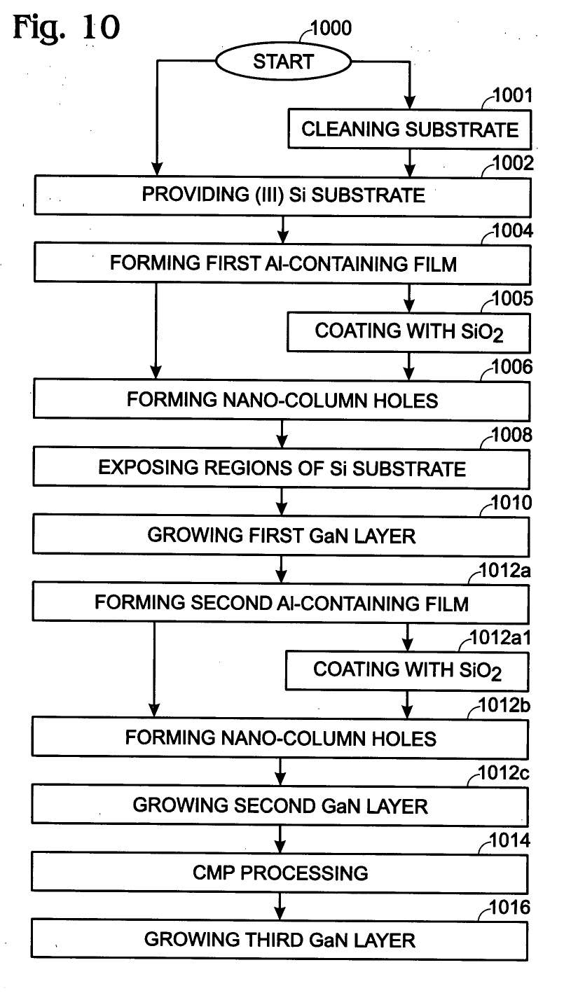

FIG. 10 is a flowchart illustrating a method for forming a matching thermal expansion interface between Si and GaN films. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1000.

Step 1002 provides a (111) Si substrate. Step 1004 forms a first aluminum (Al)-containing film in compression overlying the Si substrate. Step 1006 forms nano-column holes in the first Al-containing film. As noted above, an AAO process may be used to form the nano-column holes. However, the invention is not limited to just AAO technology. Step 1008 exposes regions of the underlying Si substrate. Using a lateral nanoheteroepitaxy overgrowth (LNEO) process, Step 1010 selectively grows a first GaN layer from the exposed regions, covering the first Al-containing film. That is, the GaN is more likely to grow on the exposed Si (or GaN) regions than it is on AAO. Typically, the first GaN layer has a thickness in a range of 0.3 to 1 micrometers. Step 1012 repeats Step 1004, 1006, 1008, and 1010. That is, Step 1012a forms a second Al-containing film in compression, Step 1012b forms nano-column holes in the second Al-containing film. In this case, regions of the first GaN layer are exposed. Step 1012c selectively grows a second GaN layer using the LNEO process. Typically, the second GaN layer has a thickness in the range of 1 to 4 micrometers.

In one aspect, forming the first and second Al-containing films in Step 1004 and 1012a includes each step forming an AlN film having a thickness in a range of about 5 to 500 nm. In another aspect, the film is Al, and the thickness in the range of 0.5 to 1.5 micrometers. In another aspect, Steps 1004 and 1012a each form an AlN/graded AlGaN (Al₁₋ₓGaₓN (0<x<1)) stack, where the AlN film has a thickness in a range of about 5 to 500 nm and the AlGaN has a thickness in a range of about 5 to 500 nm. In a different aspect, Steps 1004 and 1012a each form an AlN/AlGaN/GaN stack, where the AlN film has a thickness in a range of about 5 to 500 nm, the AlGaN is graded and has a thickness in a range of about 5 to 500 nm, and the GaN has a thickness in a range of about 5 to 600 nm.

In one aspect, the nano-column holes formed in Steps 1006 and 1012b have a diameter in a range of about 10 to 100 nm, separated from adjacent nano-column holes by a distance in a range of about 50 to 200 nm.

In another aspect, selectively growing the second GaN layer in Step 1012c includes forming a GaN top surface. Then, Step 1014 performs a chemical mechanical polishing (CMP) on the GaN top surface, and Step 1016 selectively grows a third a GaN layer using the LNEO process overlying the CMP'ed GaN top surface.

Optionally, Step 1001 cleans a top surface of the Si substrate using an in-situ hydrogen treatment, prior to forming the first Al-containing film overlying the Si substrate.

In one aspect, selectively growing the first and GaN layers in Steps 1010 and 1012c includes heating the Si substrate to a temperature in a range of 700 to 1200° C.

In a different aspect, Steps 1005 and 1012a1 coat the first and second Al-containing films, respectively, with Si dioxide, prior to selectively growing the first and second GaN layers. Then, selective growing the first and second GaN layers in Steps 1010 and 1012c includes increasing the selectively of the GaN growth in response to coating the first and second Al-containing films with Si dioxide. That is, GaN is even less likely to grow on silicon dioxide than AAO.

A GaN-on-Si thermal expansion interface and associated fabrication process have been provided. Some examples and materials, dimensions, and process steps have been given to illustrate the invention. However, the invention is not limited to merely these examples. Other variations and embodiments of the invention will occur to those skilled in the art.

1. A method for forming a matching thermal expansion interface between silicon (Si) and gallium nitride (GaN) films, the method comprising:
providing a (111) Si substrate;
forming a first aluminum (Al)-containing film in compression overlying the Si substrate;
forming nano-column holes in the first Al-containing film;
exposing regions of the underlying Si substrate;
using a lateral nanoheteroepitaxy overgrowth (LNEO) process, selectively growing a first GaN layer from the exposed regions, covering the first Al-containing film; and,
repeating the above-mentioned processes, forming a second Al-containing film in compression, forming nano-column holes in the second Al-containing film, and selectively growing a second GaN layer using the LNEO process.

2. The method of claim 1 wherein forming the first and second Al-containing films includes forming an AIN film having a thickness in a range of about 5 to 500 nanometers (nm).

3. The method of claim 1 wherein forming the first and second Al-containing films includes forming an AlN/graded AlGaN (Al₁₋ₓGaₓN (0<×<1)) stack, where the AlN film has a thickness in a range of about 5 to 500 nm and the AlGaN has a thickness in a range of about 5 to 500 nm.

4. The method of claim 1 wherein forming the first and second Al-containing films includes forming an AlN/AlGaN/GaN stack, where the AlN film has a thickness in a range of about 5 to 500 nm, the AlGaN is graded and has a thickness in a range of about 5 to 500 nm, and the GaN has a thickness in a range of about 5 to 500 nm.

5. The method of claim 1 wherein forming the first and second Al-containing films includes forming an Al film having a thickness in a range of 0.5 to about 1.5 micrometers.

6. The method of claim 1 wherein forming the nano-column holes includes forming nano-column holes having a diameter in a range of about 10 to 100 nm, separated from adjacent nano-column holes by a distance in a range of about 50 to 200 nm.

7. The method of claim 1 wherein selectively growing the second GaN layer includes forming a GaN top surface; and,
the method further comprising:
performing a chemical mechanical polishing (CMP) on the GaN top surface; and,
selectively growing a third GaN layer using the LNEO process overlying the CMTP'ed GaN top surface.

8. The method of claim 1 further comprising:
prior to forming the first Al-containing film overlying the Si substrate, cleaning a Si substrate top surface using an in-situ hydrogen treatment.

9. The method of claim 1 wherein selectively growing the first and second GaN layers includes heating the Si substrate to a temperature in a range of 700 to 1200° C.

10. (canceled)

11. The method of claim 1 wherein selectively growing the first GaN layer includes growing a GaN layer having a thickness in a range of 0.3 to 1 micrometers; and,
wherein selectively growing the second GaN layer includes growing a GaN layer having a thickness in a range of 1 to 4 micrometers.

12. The method of claim 1 wherein forming nano-column holes in the first Al-containing film includes forming the nano-column holes using an anodized aluminum oxide (AAO) technology.

13-20. (canceled)
